(19) United States
(12) Patent Application Publication
(10) Pub. No.: US 2014/0198468 A1
(43) Pub. Date: Jul. 17, 2014

(54) FLAT PANEL DISPLAY DEVICE

(71) Applicant: SAMSUNG DISPLAY CO., LTD., Yongin-City (KR)

(72) Inventors: Jung-Hyun Kim, Yongin City (KR); Eun-Chong Lee, Jeju-si (KR); Young-June Park, Seoul (KR)

(73) Assignee: SAMSUNG DISPLAY CO., LTD., Yongin-City (KR)

(21) Appl. No.: 13/922,183

(22) Filed: Jun. 19, 2013

(30) Foreign Application Priority Data
Jan. 15, 2013 (KR) 10-2013-0004464

(51) Int. Cl. H05K 5/00; G09G 3/20

(52) U.S. Cl. CPC H05K 5/0017; G09G 3/2092
USPC 361/760

(57) ABSTRACT

Provided is a flat panel display device. The flat panel display device includes a board unit having a board surface, and a display unit facing the board unit, the display unit having a second surface facing the board surface and a first surface opposite to the second surface and for allowing an image to be displayed thereon, wherein the display unit transmits external light through the first surface and the second surface, to allow the board surface to be seen through the first surface of the display unit.

### CROSS-REFERENCE TO RELATED PATENT APPLICATION

This application claims priority to and the benefit of Korean Patent Application No. 10-2013-0004464, filed on Jan. 15, 2013, in the Korean Intellectual Property Office, the disclosure of which is incorporated herein in its entirety by reference.

### BACKGROUND

1. Field

The present invention relates to a flat panel display device.

2. Description of the Related Art

A flat panel display device including an organic light emitting display device has an expansive application range, for example, ranging from a personal portable device such as a mobile phone, a tablet PC, etc. to a television.

The organic light emitting device may be formed as a transparent display device by including a transparent thin film transistor or a transparent organic light emitting device therein, or by separating a light emitting area from an external light transmission area. Additionally, the organic light emitting display device may be formed as a flexible flat panel display device by having a substrate or an internal device formed of a flexible material.

However, because a typical flat panel display device includes various devices, such as cameras, sensors, operation buttons, etc., on a surface where a screen is implemented, there are dead spaces corresponding to the devices.

### SUMMARY

The present invention provides a fiat panel display device displaying a large or maximum sized screen.

According to an aspect of the present invention, there is provided a flat panel display device including: a board unit having a board surface; and a display unit facing the board unit, the display unit having a second surface facing the board surface and a first surface opposite to the second surface and configured to allow an image to be displayed thereon, wherein the display unit is configured to transmit external light through the first surface and the second surface, to allow the board surface to be seen through the first surface of the display unit.

The display unit may further include a touch sensing unit.

The touch sensing unit may be at the first surface.

The flat panel display device may further include an adhesive layer between the board surface of the board unit and the second surface of the display unit.

The flat panel display device may further include a support unit configured to support at least a lateral surface of the board unit and a lateral surface of the display unit.

A color of the board surface of the board unit may be white.

According to another aspect of the present invention, there is provided a flat panel display device including: a board unit having a board surface and including at least one electronic device at the board surface; a display unit facing the board surface of the board unit and including an image displaying unit configured to display an image and to allow the board surface to be seen through the image displaying unit; and a control unit electrically coupled to the at least one electronic device and the image displaying unit, and configured to adjust the image displaying unit based on an operation of the at least one electronic device.

The display unit may further include a touch sensing unit that is electrically coupled to the control unit.

The control unit may be configured to adjust a screen size of the image displaying unit based on an operation of the at least one electronic device.

The control unit may be configured to adjust a size of an external light transmission area of the image displaying unit based on an operation of the at least one electronic device.

The at least one electronic device may include a camera device at the board surface.

The at least one electronic device may include at least one sensing device at the board surface.

The at least one electronic device may include at least one key button at the board surface.

The at least one key button may protrude toward the display unit.

The flat panel display device may further include a protruding unit interposed between the display unit and the at least one key button.

The at least one key button may include an optical sensing device.

The display unit may be flexible.

The board unit may include a receiver unit at a region of the board surface that does not overlap with the display unit.

### BRIEF DESCRIPTION OF THE DRAWINGS

The above and other features and aspects of the present invention will become more apparent by describing in detail example embodiments thereof with reference to the attached drawings in which:

FIG. 1 is an exploded perspective view illustrating a flat panel display device, according to an example embodiment of the present invention;

FIG. 2 is a separated sectional view illustrating a flat panel display device, according to an example embodiment of the present invention;

FIG. 3 is a cross-sectional view illustrating a display unit of a flat panel display device, according to another example embodiment of the present invention;

FIGS. 4 and 5 are cross-sectional views illustrating image displaying units of a display unit, according to different example embodiments of the present invention;

FIG. 6 is a cross-sectional view of a flat panel display device, according to an example embodiment of the present invention;

FIG. 7 is a cross-sectional view of a flat panel display device, according to an example embodiment of the present invention;

FIG. 8 is a diagram illustrating a configuration of a flat panel display device, according to an example embodiment of the present invention;

FIG. 9 is an exploded perspective view of a flat panel display device of FIG. 8, according to an example embodiment of the present invention;

FIG. 10(a) is a sample screen view of a fiat panel display device of FIG. 9, according to an example embodiment of the present invention.

FIG. 10(b) is a sample view when a user uses a camera device and a sensing device, according to an example embodiment of the present invention;

FIG. 11 is an exploded perspective view of the flat panel display device of FIG. 8, according to another example embodiment of the present invention;

FIG. 12 is a partial cross-sectional view of a flat panel display device of FIG. 11, according to an example embodiment of the present invention; and

FIGS. 13 to 18 are different partial cross-sectional views of a flat panel display device of FIG. 12, according to some example embodiments.

### DETAILED DESCRIPTION

Hereinafter, embodiments of the present invention will be described in more detail with reference to the accompanying drawings.

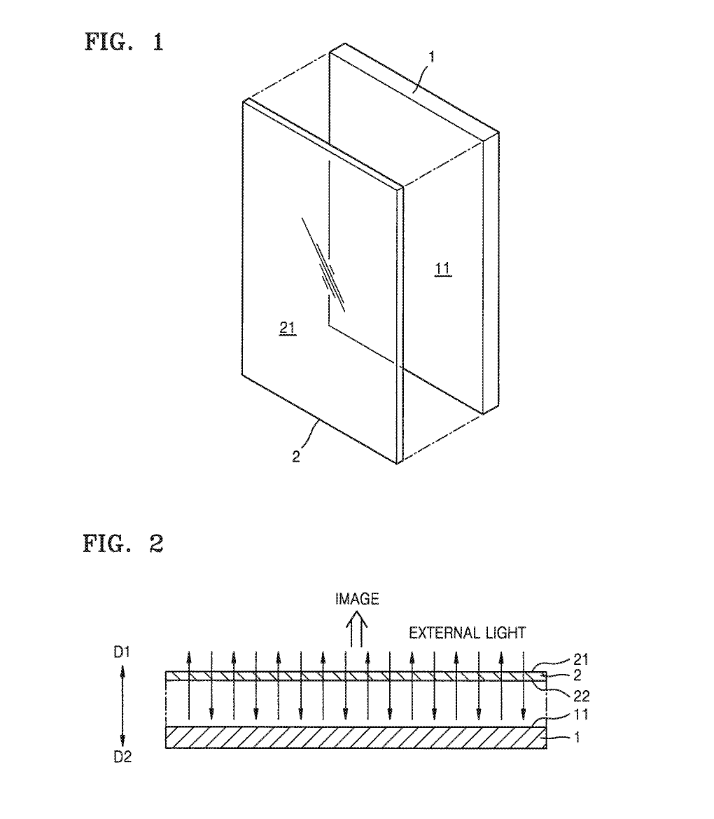

FIG. 1 is an exploded perspective view illustrating a flat panel display device, according to an embodiment of the present invention.

The flat panel display device of FIG. 1 includes a board unit 1 and a display unit 2.

The board unit 1 includes a flat panel and a board surface 11. The board unit 1 may include various electronic devices for operating the display unit 2, and the various electronic devices may be electrically coupled to the display unit 2. However, the present invention is not limited thereto, and thus, an additional board including electronic devices and a case may be coupled to the opposite side of the board surface 11.

The display unit 2 is coupled to the board unit 1, facing the board unit 1 and also includes a flat panel. The board unit 1 is coupled to the backside of the display unit 2. When seen from the front of the display unit 2, the board surface 11 of the board unit 1 can be seen because external light can be penetrated through the display unit 2.

In more detail, as shown in FIG. 2, the display unit 2 has a first surface 21 facing in a first direction D1 and a second surface 22 facing in a second direction D2 opposite to the first direction D1. An image is realized toward the first direction D1 through the first surface 21. Accordingly, a user may be located at the front of the first direction D1 with respect to the display unit 2.

Moreover, the display unit 2 is disposed to allow external light to penetrate the first side 21 and the second side 22. Accordingly, the user at the front of the first direction D1 with respect to the display unit 2 may observe the board surface 11 of the board unit 1 through the first surface 21 and the second surface 22 of the display unit 2.

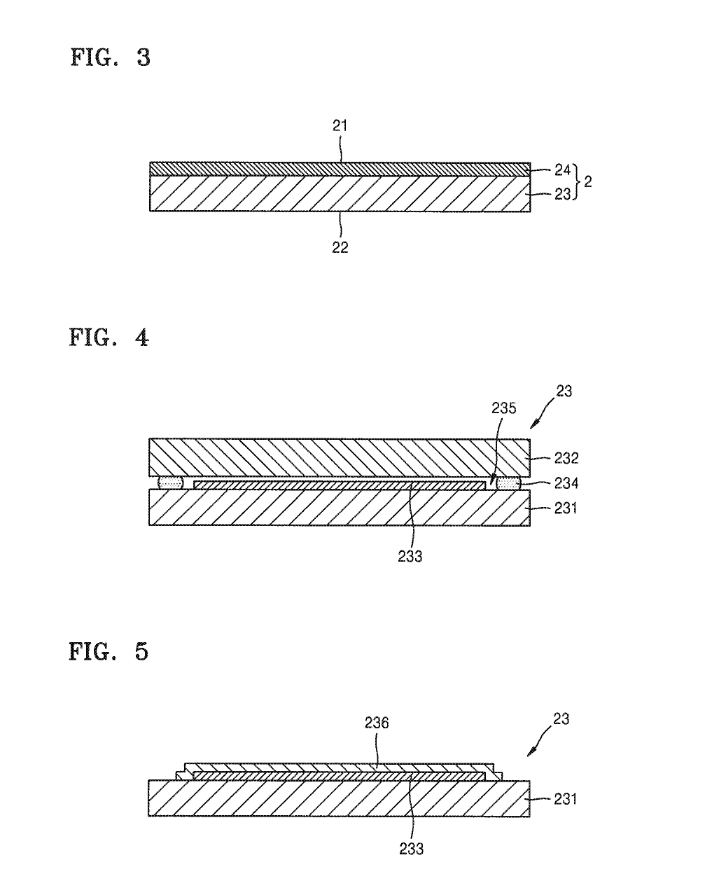

FIG. 3 is a cross-sectional view of the display unit 2, according to another embodiment of the present invention. As shown in FIG. 3, the display unit 2 may include an image displaying unit 23 and a touch sensing unit 24.

The image displaying unit 23 and the touch sensing unit 24 may be bonded to each other by an adhesive means (not shown), but the present invention is not limited thereto. Thus, the touch sensing unit 24 may be integrated into the image displaying unit 23 by depositing the touch sensing unit 24 on or inside the image displaying unit 23.

The touch sensing unit 24 may include a capacitive sensing type touch panel or a pressure sensing type touch panel.

FIGS. 4 and 5 are cross-sectional views of the image displaying unit 23, according to different embodiments of the present invention. The embodiments of FIGS. 4 and 5 represent an organic light emitting display device.

Referring to FIG. 4, the image displaying unit 23 includes an organic light emitting unit 233 on one side of a substrate 231 and a sealing substrate 232 sealing the organic light emitting unit 233.

The sealing substrate 232 may be formed of a transparent glass or plastic substrate to allow an image to be realized from the organic light emitting unit 233, and prevent external air and moisture from penetrating the organic light emitting unit 233.

The edges of the substrate 231 and the sealing substrate 232 are bonded to each other by a sealing material 234, so that a space 235 between the substrate 231 and the sealing substrate 232 is sealed. An absorbent or filler may be placed or inserted in the space 235.

As shown in FIG. 5, instead of the sealing substrate 232, the organic light emitting unit 233 may be protected from external air and/or water by forming a thin sealing film 236 on the organic light emitting unit 233. The sealing film 236 may have a structure in which a layer formed of an inorganic substance such as silicon oxide or silicon nitride and a layer formed of an organic substance such as epoxy and polyimide are alternately formed, but the present invention is not limited thereto. That is, any sealing structure on a transparent thin film may be applicable.

The embodiments of FIGS. 4 and 5 may be of a bottom emission type in which an image is realized in the direction of the substrate 231, a top emission type in which an image is realized in the direction of the sealing substrate 232 or the sealing film 236, or a dual emission type in which an image is realized in both the direction of the substrate 231 and the direction of sealing film 236.

Such an organic light emitting display device includes a light emitting region and a transmission region to realize a transparent and/or see-through display device.

The image displaying unit 23 may be realized without using an organic light emitting display device. That is, the image displaying unit 23 may be realized with various flat panel display devices transmitting external light.

Referring to FIG. 3, the touch sensing unit 24 may be formed on the top surface of the sealing substrate 232, according to one embodiment of the image displaying unit 23 of FIG. 4, or may be formed on the top surface of the sealing film 236, according to another embodiment of the image displaying unit 23 of FIG. 5. However, the present invention is not limited thereto. That is, the touch sensing unit 24 may be formed at the bottom surface of the substrate 231 of the image displaying unit 23 shown in FIGS. 4 and 5.

In some embodiments, the touch sensing unit 24 may be formed in the image displaying unit 23. For example, the touch sensing unit 24 may be formed at the bottom surface of the sealing substrate 232 of the image displaying unit 23 shown in FIG. 4, i.e., between the sealing substrate 232 and the organic light emitting unit 233, or at the top surface of the substrate 231, i.e., between the substrate 231 and the organic light emitting unit 233. The touch sensing unit 24 may also be formed at the bottom surface of the sealing film 236 of the image displaying unit 23 shown in FIG. 5, i.e., between the sealing film 236 and the organic light emitting unit 233, or at the top surface of the substrate 231, i.e., between the substrate 231 and the organic light emitting unit 233.

Referring to FIG. 3, an assembly in which the image displaying unit 23 and the touch sensing unit 24 are combined (or coupled) together becomes the display unit 2. A first surface 21 may be one surface of the touch sensing unit 24 and a second surface 22 may be one surface of the image displaying unit 23.

However, the present invention is not limited thereto. Although not shown in the drawings, the first surface 21 may be one surface of the image displaying unit 23 and the second surface 22 may be one surface of the touch sensing unit 24. Moreover, as mentioned above, when the touch sensing unit 24 is formed in the image displaying unit 23, the first surface 21 and the second surface 22 may both be surfaces of the image displaying unit 23, respectively.

The embodiments of the display unit 2 may be applicable to all embodiments of the present invention that will be described below.

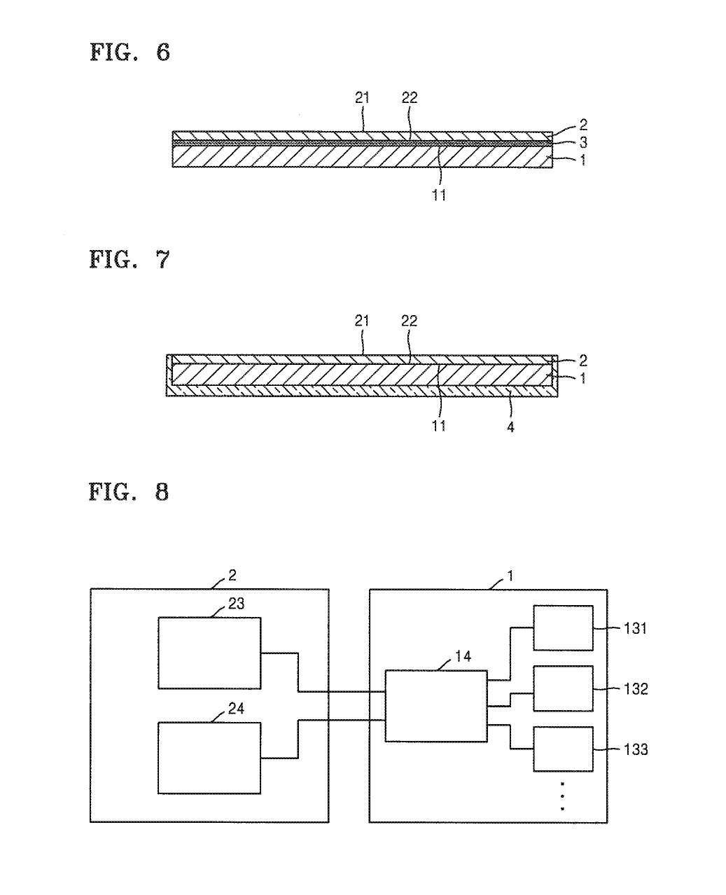

FIG. 6 is a cross-sectional view of a flat panel display device, according to an embodiment of the present invention. An adhesive layer 3 is interposed between a board unit 1 and a display unit 2 to combine (or couple) them together. The adhesive layer 3 may be interposed between a board surface 11 of the board unit 1 and a second surface 22 of the display unit 2. The adhesive layer 3 may be transparent so that a user's view may not be disturbed when observing the board surface 11 through the display unit 2.

FIG. 7 is a cross-sectional view of a flat panel display device, according to an embodiment of the present invention. A board unit 1 and a display unit 2 may be combined (or coupled) by a support unit 4. As shown in FIG. 7, the support unit 4 may be provided to support at least a lateral surface of the board unit 1 and a lateral surface of the display unit 2, and also may be provided to support a bottom surface of the board unit 1, i.e., the opposite surface of the board surface 11 of the board unit 1. However, the present invention is not limited thereto. Although not shown in the drawing, the support unit 4 may be provided to support only the lateral surface of the board unit 1 and the lateral surface of the display unit 2. In addition, although not shown in the drawings, various electronic devices for operating the display unit 2 may be installed in the support unit 4. Accordingly, the support unit 4 may serve as a case, in which embodiment, a cover glass such as reinforced glass may be further installed at the top of the first surface 21 of the display unit 2 and its edge may be fixed at the support unit 4, so that one complete device may be configured.

According to the present invention, the board surface 11 of the board unit 1 may be white in color. Accordingly, when seeing the board surface 11 through the display unit 2, a user may observe the board surface 11 of white color.

If the board surface 11 is white, because the display unit 2 is a transparent display device, a user may see a white screen even when the flat panel display device of the present invention is turned off.

Additionally, power consumption may be reduced by selectively using only a certain part of the screen of the display unit 2. For example, only a desired screen may pop up at the display unit 2. When simple tasks such as sending and receiving a message are performed, only a small message window may pop up. Additionally, although three to four screens may pop up at one time, they may overlap one other.

Additionally, because a white color board surface is observed through a display unit 2, a user may selectively choose for light to be emitted from a used portion of a screen. Accordingly, power consumption may be drastically reduced and battery efficiency may be increased.

The board surface 11 may not be pure white in color and may be a high-brightness color.

However, the present invention is not limited thereto. That is, the board surface 11 may be black in color or a low-brightness color such as a blue color. Accordingly, a user may clearly distinguish a displayed window from the board surface 11, i.e., a background.

Moreover, according to an embodiment of the present invention, by allowing a user to observe the board surface 11 through the transparent display unit 2, a variety of visual effects that the user wants may be obtained.

FIG. 8 is a diagram illustrating a configuration of a flat panel display device, according to an embodiment of the present invention.

As mentioned above, the flat panel display device includes a board unit 1 and a display unit 2.

The board unit 1 may include at least one electronic device. As shown in FIG. 8, the board unit 1 may include a plurality of electronic devices 131, 132, and 133.

The display unit 2 may include an image displaying unit 23 and a touch sensing unit 24. The touch sensing unit 24 may be selectively provided, and if there is another input means, the touch sensing unit 24 may be omitted.

The board unit 1 and the display unit 2 may be applicable to all the above-mentioned embodiments.

The electronic devices 131, 132, and 133, the image displaying unit 23, and the touch sensing unit 24 may be electrically coupled to the control unit 14. The control unit 14 (e.g. controller 14) is configured to adjust (or control) the image displaying unit 23 based on operations of the electronic devices 131, 132, and 133.

As shown in FIG. 8, the control unit 14 may be mounted at the board unit 1. However, the present invention is not limited thereto. That is, the control unit 14 may be separated from the board unit 1.

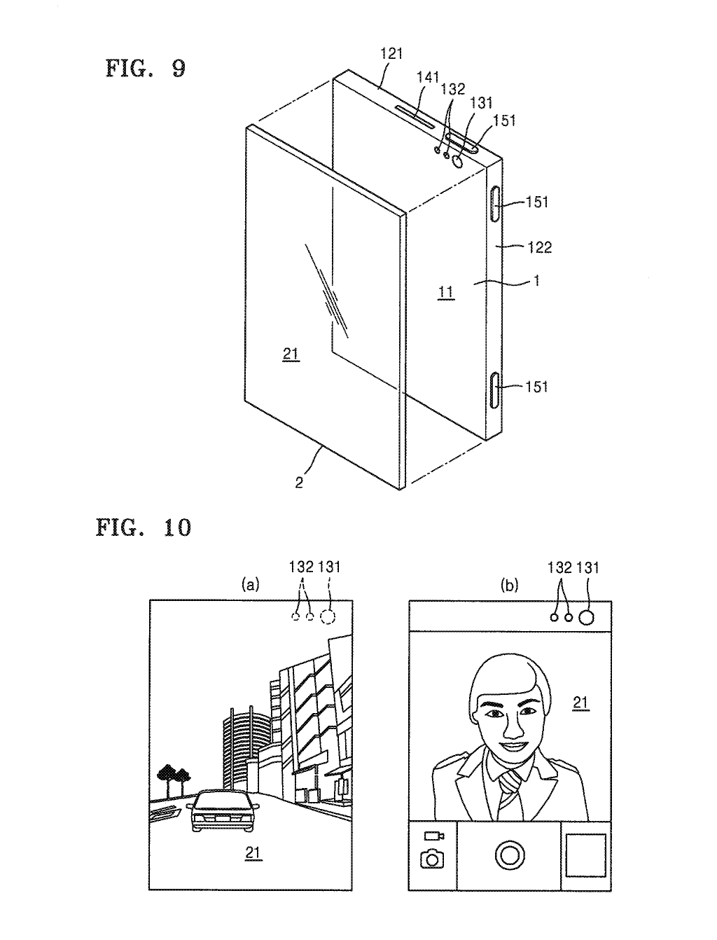

FIG. 9 is an exploded perspective view of the flat panel display device of FIG. 8, according to an embodiment of the present invention. The flat panel display device of FIG. 9 may, for example, be a mobile phone or a tablet PC.

Referring to FIGS. 8 and 9, according to an embodiment of the flat panel display device of the present invention, like the above-mentioned embodiments, a display unit 2 is disposed to face a board surface 11 of a board unit 1. The display unit 2 includes an image displaying unit 23 through which a board surface 11 is seen and where an image is displayed through a first surface 21. Although not shown in the drawings, a cover glass formed of reinforced glass may be further provided at the front surface of the display unit 2.

The board unit 1 may include a first lateral surface 121 and a second lateral surface 122 at the outer side of the board surface 11. The first lateral surface 121 and the second lateral surface 122 may not overlap with the display unit 2 when the board unit 1 is combined (or coupled) with the display unit 2, and also, may be vertical (or perpendicular) to the board surface 11. However, the present invention is not limited thereto, and thus, the first lateral surface 121 and the second lateral surface 122 may be tilted (e.g., be at an angle) with respect to the board surface 11.

A receiver unit 141 may be disposed at the first lateral surface 121, and a system providing orientation to sound (e.g., Directed Audio Sound System) may be applied to the receiver unit 141, so that sound may be directed toward the user's ear.

In addition, various operation buttons 151 may be further positioned at the first lateral surface 121 and the second lateral surface 122. The operation button 151 may include a power input button, a volume control button, a home key button for returning to a main screen, a menu key button, and/or a back key button returning to a previous screen.

Moreover, electronic devices that are electrically coupled to the control unit 14 may be disposed at the board surface 11. That is, a first electronic device such as a camera device 131 and a second electronic device such as a sensing device 132 may be disposed at the board surface 11. The sensing device 132 may include a proximity sensor and/or an intensity measurement sensor.

The camera device 131 and the sensing device 132 at the board surface 11 may capture an image transmitted through the display unit 2.

Additionally, if a user operates the camera device 131 and the sensing device 132 while an image is being displayed (or realized) through the image displaying unit 23, the control unit 14 reduces a screen size of the image displaying unit 23 to allow an image transmitted through the display unit 2 to be smoothly (or flawlessly) delivered to the camera device 131 and the sensing device 132.

FIG. 10(a) is a sample screen view of a flat panel display device of FIG. 9, according to an embodiment of the present invention.

For example, as shown in FIG. 10(a), while viewing an image, a user may use the entire first surface 21 of the display unit 2 of FIG. 9 as a screen. Accordingly, the user views a large area screen corresponding to the entire surface of a flat panel display device. At this point, the camera device 131 and the sensing device 132 are hidden by the screen.

FIG. 10(b) is a sample screen view when a user uses a camera device and a sensing device, according to an embodiment of the present invention.

Also, as shown in FIG. 10(b), when a user wants to use the camera device 131 and the sensing device 132, a screen size on the first surface 21 may be reduced to exclude (or uncover) the portions of the camera device 131 and the sensing device 132, and accordingly, an image transmitted through the display unit 2 may be smoothly (or flawlessly) delivered to the camera device 131 and the sensing device 132.

According to embodiments of the present invention, a large area screen is used, and additionally a camera device in a screen direction may be used without inconvenience.

The control unit 14 is configured to adjust the size of an external light transmission region of the image displaying unit 23 without reducing a screen size when the camera device 131 and the sensing device 132 operate. That is, external light is prevented from passing through the other portion of the image displaying unit 23 but allowed to pass through a portion corresponding to the camera device 131 and the sensing device 132.

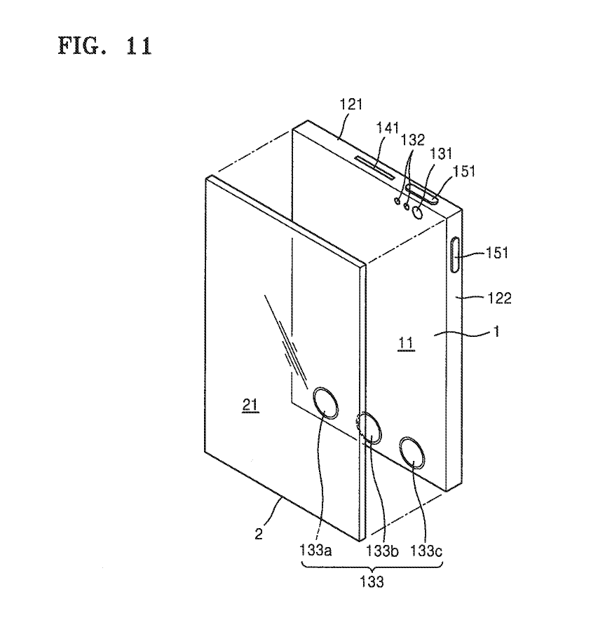

FIG. 11 is an exploded perspective view of the flat panel display device of FIG. 8, according to another embodiment of the present invention. The flat panel display device of FIG. 11 may, for example, be a mobile phone or a tablet PC.

According to an embodiment of FIG. 11, unlike the embodiment of FIG. 9, a key button unit 133 is disposed at a board surface 11. The key button unit 133 is an electronic device that is electrically coupled to the control unit 14 as shown in FIG. 8. According to the embodiment of FIG. 11, the key button unit 133 may include a first key button 133a, such as a menu key; a second key button 133b, such as a home key; and a third button 133c, such as a back key. However, the present invention is not limited thereto, and thus, only one button including all functions may be disposed at the center.

According to embodiments of the present invention, because the display unit 2 is transparent to transmit external light, a user may recognize the key button unit 133 at the other surface of the display unit 2 and accordingly, may operate the key button unit 133 by pressing or touching a portion (or region) of the first surface 21 of the display unit 2 corresponding to the key button unit 133. Accordingly, a screen size of the display unit 2 may be reduced to expose a portion of the key button unit 133.

The control unit 14 controls the image displaying unit 23 to have a higher external light transmission in an area corresponding to the key button unit 133 than in other areas, so that a user may identify and press the key button unit 133 without difficulties. Additionally, as a user presses another button, the control unit 14 may reduce a screen size of the image displaying unit 23 to allow an area corresponding to the key button unit 133 to be exposed, so that it is recognized that the user presses the key button unit 133.

The key button unit 133 may be operated based on the pressure of the user's finger.

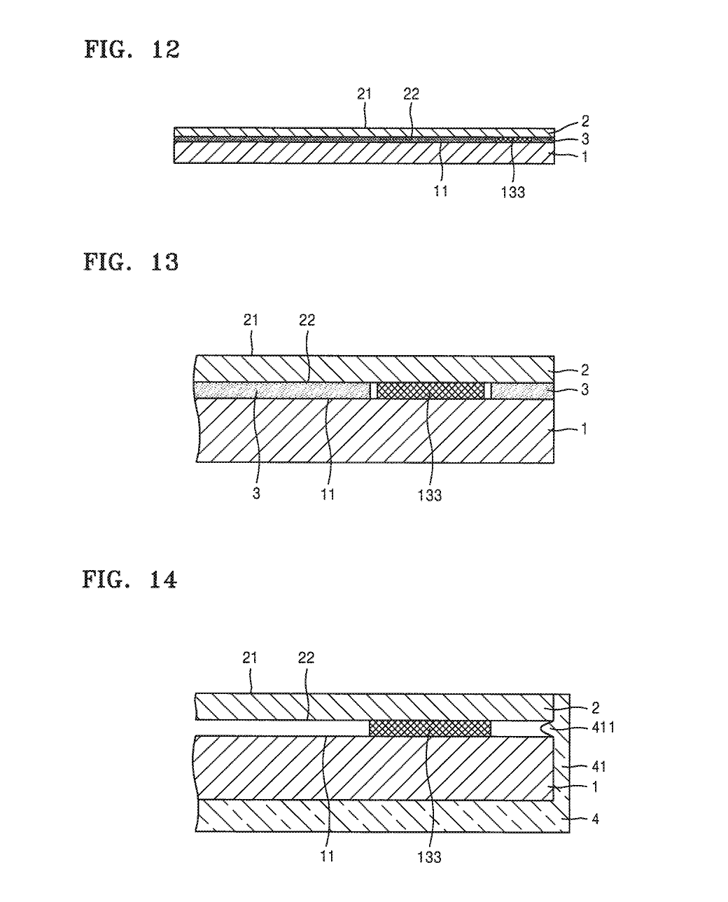

FIG. 12 is a partial cross-sectional view of a flat panel display device of FIG. 11, according to an embodiment of the present invention. As shown in FIG. 12, the key button unit 133 may protrude toward the display unit 2.

In this embodiment, as shown in FIG. 12, the board unit 1 is spaced a distance (e.g., a predetermined interval) apart from the display unit 2 based on the protruding height of the key button unit 133.

FIG. 13 is a partial cross-sectional view of FIG. 12, according to an embodiment of the present invention. As shown in FIG. 13, when an adhesive layer 3 is interposed between a board unit 1 and a display unit 2, it may not be formed at the position of a key button unit 133. Also, the adhesive layer 3 may have ample flexibility so that the key button unit 133 may be pressed as a user presses a first surface 21 of the display unit 2.

FIG. 14 is a partial cross-sectional view of another embodiment of the present invention. As shown in FIG. 14, the board unit 1 and the display unit 2 may be supported by a support unit 4, and a protrusion 411 may be formed at a lateral surface 41 of the support unit 4. The protrusion 411 is inserted between the board unit 1 and the display unit 2 so that they are spaced a distance (e.g., a predetermined interval) apart from each other. The protrusion 411 may be formed with a shock-absorbing material and/or shape so that the key button unit 133 may be pressed by the display unit 2 as a user presses the first surface 21 of the display unit 2.

Moreover, the key button unit 133 may operate based on the pressure of the user's finger but may not protrude toward the display unit 2.

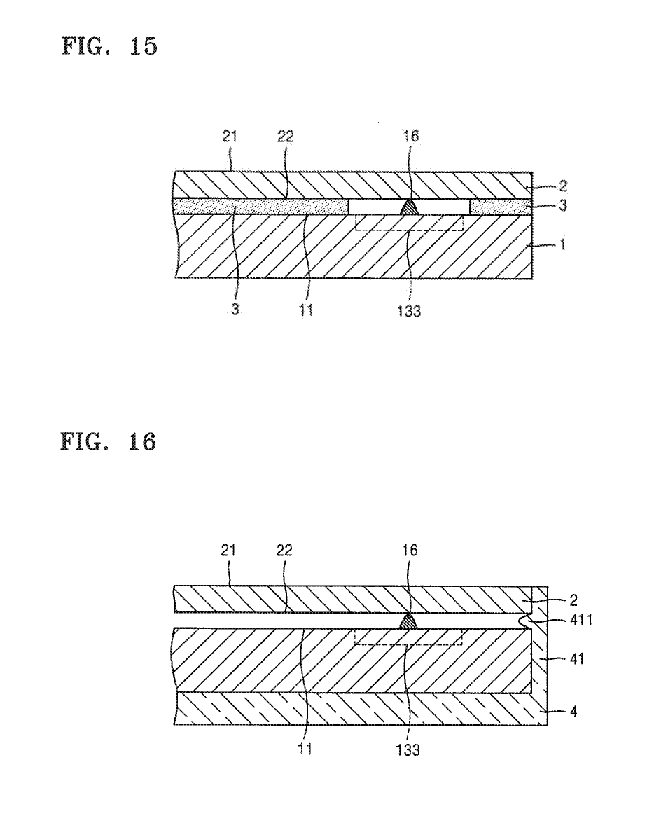

For example, as shown in FIGS. 15 and 16, the key button unit 133 may be disposed below the board surface 11 and seated in the board unit 1. FIG. 15 is a partial cross-sectional view of the fiat panel display device of FIG. 13 when an adhesive layer 3 is interposed between a board unit 1 and a display unit 2, according to an embodiment of the present invention. FIG. 16 is a partial cross-sectional view of the flat panel display device of FIG. 14 when the board unit 1 and the display unit 2 are combined (or coupled) by the support unit 4, according to an embodiment of the present invention.

In the embodiments of FIGS. 15 and 16, a protruding unit 16 may be further interposed between the key button unit 133 and the second surface 22 of the display unit 2. The protruding unit 16 may be formed on the top surface of the key button unit 133, but is not limited thereto. That is, the protruding unit 16 may be formed on a second surface 22 of the display unit 2.

According to some embodiments, the display unit 2 may be flexible. Accordingly, when a user presses a portion of the first surface 21 of the display unit 2 corresponding to the key button unit 133, a corresponding portion of the display unit 2 is compressed in the direction of the board unit 1 so that the key button unit 133 may operate without error.

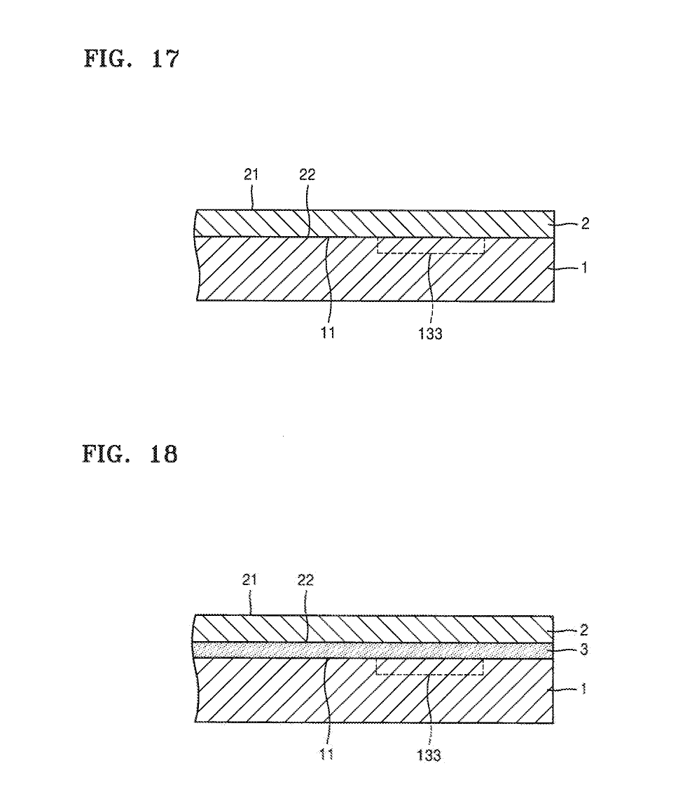

Additionally, as shown in FIGS. 17 and 18, the key button unit 133 may be an optical sensing device. In such embodiments, the key button unit 133 that is an optical sensing device may recognize an intensity difference of an external light transmitted through the display unit 2 so that it may serve as a key button.

Of course, as mentioned above, a user may control the control unit 14 in order to operate the key button unit 133 in advance by an operation of one or more key buttons.

When the key button unit 133 is an optical sensing device, as shown in FIG. 17, the board unit 1 and the display unit 2 may be close to each other without being spaced apart from each other, and as shown in FIG. 18, the adhesive layer 3 may be interposed between the board unit 1 and the display unit 2 across the entire screen. Of course, as shown in FIG. 7, the board unit 1 and the display unit 2 may be supported by the support unit 4.

According to an embodiment of the present invention, because the entire surface of a flat panel display device is used as a screen, a large area screen may be realized.

Additionally, because a white color board surface is observed through a display unit, a user may selectively choose for light to be emitted from a used portion of a screen. Accordingly, power consumption may be drastically reduced and battery efficiency may be increased.

Moreover, by allowing a user to observe the board surface through a transparent display unit, a variety of visual effects that the user wants may be obtained.

While the present invention has been particularly shown and described with reference to example embodiments thereof, it will be understood by those of ordinary skill in the art that various changes in form and details may be made therein without departing from the spirit and scope of the present invention as defined by the following claims, and equivalents thereof.

What is claimed is:

1. A flat panel display device comprising:
a board unit having a board surface; and
a display unit facing the board unit, the display unit having a second surface facing the board surface and a first surface opposite to the second surface and configured to allow an image to be displayed thereon, wherein
the display unit is configured to transmit external light through the first surface and the second surface, to allow the board surface to be seen through the first surface of the display unit.

2. The flat panel display device of claim 1, wherein the display unit further comprises a touch sensing unit.

3. The flat panel display device of claim 2, wherein the touch sensing unit is at the first surface.

4. The flat panel display device of claim 1, further comprising an adhesive layer between the board surface of the board unit and the second surface of the display unit.

5. The flat panel display device of claim 1, further comprising a support unit configured to support at least a lateral surface of the board unit and a lateral surface of the display unit.

6. The flat panel display device of claim 1, wherein a color of the board surface of the board unit is white.

7. A flat panel display device comprising:
a board unit having a board surface and comprising at least one electronic device at the board surface;
a display unit facing the board surface of the board unit and comprising an image displaying unit configured to display an image and to allow the board surface to be seen through the image displaying unit; and
a control unit electrically coupled to the at least one electronic device and the image displaying unit, and configured to adjust the image displaying unit based on an operation of the at least one electronic device.

8. The flat panel display device of claim 7, wherein the display unit further comprises a touch sensing unit that is electrically coupled to the control unit.

9. The flat panel display device of claim 7, wherein the control unit is configured to adjust a screen size of the image displaying unit based on an operation of the at least one electronic device.

10. The flat panel display device of claim 7, wherein the control unit is configured to adjust a size of an external light transmission area of the image displaying unit based on an operation of the at least one electronic device.

11. The flat panel display device of claim 7, wherein the at least one electronic device comprises a camera device at the board surface.

12. The flat panel display device of claim 7, wherein the at least one electronic device comprises at least one sensing device at the board surface.

13. The flat panel display device of claim 7, wherein the at least one electronic device comprises at least one key button at the board surface.

14. The flat panel display device of claim 13, wherein the at least one key button protrudes toward the display unit.

15. The flat panel display device of claim 13, further comprising a protruding unit interposed between the display unit and the at least one key button.

16. The flat panel display device of claim 13, wherein the at least one key button comprises an optical sensing device.

17. The flat panel display device of claim 13, wherein the display unit is flexible.

18. The flat panel display device of claim 7, wherein the board unit comprises a receiver unit at a region of the board surface that does not overlap with the display unit.
